(19) United States
(12) Patent Application Publication
(10) Pub. No.: US 2006/0001969 A1
(43) Pub. Date: Jan. 5, 2006

(54) Gratings, related optical devices and systems, and methods of making such gratings

(75) Inventors: Jian Jim Wang, Orefield, PA (US); Xuegong Deng, Piscataway, NJ (US); Lei Chen, Princeton, NJ (US)

Correspondence Address: FISH & RICHARDSON PC, P.O. BOX 1022, MINNEAPOLIS, MN, 55440-1022, US

(73) Assignee: NanoOpto Corporation, Somerset, NJ (US)

(21) Appl. No.: 10/989,448

(22) Filed: Nov. 15, 2004

Related U.S. Application Data
(63) Continuation-in-part of application No. 10/918,299, filed on Aug. 13, 2004.
(60) Provisional application No. 60/584,967, filed on Jul. 2, 2004.

(51) Int. Cl. G02B 5/18; H01L 21/338

(52) U.S. Cl. 359/494; 359/483

(57) ABSTRACT

Gratings and related devices and systems are disclosed.

### CROSS-REFERENCE TO RELATED APPLICATIONS

This application claims priority under 35 U.S.C. § 119 to Provisional Patent Application No. 60/584,967, entitled “RECISION PHASE RETARDERS AND WAVEPLATES AND TRIM RETARDERS BY USING ATOMIC LAYER DEPOSITION (ALD) ONTO A SAW-TOOTH PRE-PATTERNED SURFACE AND THE METHOD TO MAKE SAW-TOOTH SHAPED GRATING,” and filed on Jul. 2, 2004. This application is also a continuation in part and claims priority under 35 U.S.C. §120 to U.S. patent application Ser. No. 10/918,299, entitled “OPTICAL RETARDERS AND RELATED DEVICES AND SYSTEMS,” filed on Aug. 13, 2004. The entire contents of Provisional Patent Application No. 60/584,967 and U.S. patent application Ser. No. 10/918,299 are hereby incorporated by reference.

### TECHNICAL FIELD

This invention relates to gratings, related optical devices and systems, and methods of making such gratings.

### BACKGROUND

Optical devices and optical systems are commonly used where manipulation of light is desired. Examples of optical devices include lenses, polarizers, optical filters, antireflection films, retarders (e.g., quarter-waveplates), and beam splitters (e.g., polarizing and non-polarizing beam splitters).

### SUMMARY

In general, in one aspect, the invention features an article that includes a layer of a first material having a cross-sectional profile comprising at least one peak and at least one trough and a layer of a second material adjacent the layer of the first material, the layer of the second material having a cross-sectional profile substantially the same as the cross-sectional profile of the layer of the first material, wherein the first and second materials are different and the article is birefringent for a wavelength, λ, where λ is in a range from about 150 nm to about 2,000 nm.

Where two layers have substantially the same cross-sectional profile, the cross-section of each portion (e.g., facet) of a surface of the first layer has a corresponding portion of a surface of the second layer. As an example, in some embodiments, the corresponding portions have substantially the same orientation with respect to a common reference system. For example, the angular orientation of a portion of a surface with respect to the reference system is within about 10% or less of the angular orientation of a corresponding portion in another layer with respect to the reference system (e.g., about 9% or less, about 8% or less, about 7% or less, about 6% or less, about 5% or less, about 4% or less, about 3% or less, about 2% or less, about 1% or less, about 0.5% or less, 0.1% or less). Furthermore, as another example, in certain embodiments, a cross-sectional dimension of a portion is within about 10% or less of the cross-sectional dimension of a corresponding portion in another surface (e.g., about 9% or less, about 8% or less, about 7% or less, about 6% or less, about 5% or less, about 4% or less, about 3% or less, about 2% or less, about 1% or less, about 0.5% or less, 0.1% or less). In some embodiments, where a portion of a first surface is curved, a corresponding portion in another surface has a radius of curvature within about 10% or less of that first surface portion's radius of curvature (e.g., about 9% or less, about 8% or less, about 7% or less, about 6% or less, about 5% or less, about 4% or less, about 3% or less, about 2% or less, about 1% or less, about 0.5% or less, 0.1% or less).

In general, in another aspect, the invention features an article that includes a first layer including a first material and having a surface with a cross-sectional profile including a plurality of portions and at least one peak and at least one trough. The article also includes a second layer adjacent the first layer, the second layer including a second material and having a surface with a cross-sectional profile including a plurality of portions corresponding to the portions of the cross-sectional profile of the surface of the first layer and at least one peak and at least one trough. The corresponding portions have an angular orientation within about 10% or less of each other and a length within about 10% or less of each other, the first and second materials are different and the article is birefringent for a wavelength, λ, where λ is in a range from about 150 nm to about 2,000 nm.

In a further aspect, the invention features an article that includes a first layer including a first material and having a surface with a periodic cross-sectional profile that includes a plurality of portions. The article also includes a second layer adjacent the first layer, the second layer including a second material and having a surface with a cross-sectional profile that includes a plurality of portions corresponding to the portions of the cross-sectional profile of the surface of the first layer. Corresponding portions have an angular orientation within about 10% or less of each other and a length within about 10% or less of each other, the first and second materials are different and a period of the cross-sectional profile of the surface of the first layer is about 2,000 nm or less.

In another aspect, the invention features an article that includes a first layer including a first material extending in a plane and including a surface having a plurality of facets that are non-normal and non-parallel to the plane, the surface of the first layer having a cross-sectional profile that includes at least one peak and at least one trough. The article also includes a second layer adjacent the first layer, the second layer including a second material adjacent and having a perpendicular thickness that is substantially constant, wherein the first and second materials are different and the article is birefringent for a wavelength, λ, where λ is in a range from about 150 nm to about 2,000 nm.

In a further aspect, the invention features an article that includes a first layer including a first material extending in a plane and including a surface having a plurality of facets that are non-normal and non-parallel to the plane and having a periodic cross-sectional profile. The article also includes a second layer adjacent the first layer, the second layer including a second material and having a perpendicular thickness that is substantially constant, wherein a period of the cross-sectional profile of the surface of the first layer is about 2,000 nm or less.

In yet a further aspect, the invention features an article that includes a plurality of layers each having a surface with saw-tooth cross-sectional profile, wherein the article is birefrinegent for radiation having a wavelength, λ, from about 150 nm to about 2,000 mm.

Embodiments of the articles can include one or more of the following features.

The articles can further include a third layer adjacent the second layer, the third layer including a third material, wherein the second and third materials are different and the third layer has surface having a cross-sectional profile including a plurality of portions corresponding to the portions of the cross-sectional profile of the surface of the first layer. The first and third materials can be the same. The articles can further include a fourth layer adjacent the third layer, the fourth layer including a fourth material, wherein the third and fourth materials are different and the fourth layer has surface having a cross-sectional profile including a plurality of portions corresponding to the portions of the cross-sectional profile of the surface of the first layer. The second and fourth materials can be the same.

A perpendicular thickness of the second layer can be substantially constant. The first layer can extend in a plane and the portions of the cross-sectional profile of the surface of the first layer can include a plurality of facets that are non-normal and non-parallel to the plane. The surface of the first layer can have a periodic cross-sectional profile. The cross-sectional profile of the surface of the first layer can have a period of about 2,000 nm or less (e.g., about 1,500 nm or less, about 1,000 nm or less, about 800 nm or less, about 700 nm or less, about 600 nm or less, about 500 mm or less, about 400 nm or less, about 300 nm or less, about 200 nm or less, about 100 nm or less). A period of the cross-sectional profile of the surface of the first layer can be triangular, trapezoidal, or rectangular. In some embodiments, the surface of the first layer has a saw-tooth cross-sectional profile.

The articles can have a phase birefringence of about π/4 or more at λ (e.g., about π/2 or more, about π or more, about 2π or more, about 4π or more).

The first material can be a semiconductor material or a dielectric material. In some embodiments, the first material includes a material selected from the group consisting of SiNₓ:H_{z}, SiOₓN_{y}:H_{z}, Al₂O₃, Ta₂O₅, Nb₂O₅, TaNbₓO_{y}, TiNbₓO_{y}, HfO₂, TiO₂, SiO₂, ZnO, LiNbO₃, a-Si, Si, ZnSe, and ZnS.

The second material can be a semiconductor material or a dielectric material. In some embodiments, the second material includes a material selected from the group consisting of SiNₓ:H_{z}, SiOₓN_{y}:H_{z}, Al₂O₃, Ta₂O₅, Nb₂O₅, TaNbₓO_{y}, TiNbₓO_{y}, HfO₂, TiO₂, SiO₂, ZnO, LiNbO₃, a-Si, Si, ZnSe, and ZnS.

In general, in a further aspect, the invention features a method that includes forming a layer of a second material by sequentially depositing a plurality of monolayers of the second material, one of the monolayers of the second material being deposited on a surface of a layer of a first material having a cross-sectional profile including a plurality of portions and at least one peak and at least one trough, wherein the layer of the second material includes a surface with a cross-sectional profile including a plurality of portions corresponding to the portions of the cross-sectional profile of the surface of the layer of the first material and at least one peak and at least one trough, the corresponding portions have an angular orientation within about 10% or less of each other and a length within about 10% or less of each other, the first and second materials are different, and the article is birefringent for a wavelength, λ, where λ is in a range from about 150 nm to about 2,000 nm.

In another aspect, the invention features a method that includes forming a layer of a second material by sequentially depositing a plurality of monolayers of the second material, one of the monolayers of the second material being deposited on a surface of a layer of a first material having a periodic cross-sectional profile including a plurality of portions and having a period of about 2,000 nm or less, wherein the first and second materials are different and the second layer has a surface including a plurality of portions each corresponding to a portion of the cross-sectional profile of the surface of the layer of the first material.

Embodiments of the methods can be used to form embodiments of the articles. Embodiments of the methods can include one or more of the following features.

The methods can further include forming a layer of a third material by sequentially depositing a plurality of monolayers of the third material, one of the monolayers of the third material being deposited on the surface of the second layer. The layer of the third material can include a surface having cross-sectional profile including a plurality of portions corresponding to the portions of the cross-sectional profile of the surface of the layer of the first material.

The methods can also include forming a layer of a fourth material by sequentially depositing a plurality of monolayers of the fourth material, one of the monolayers of the fourth material being deposited on a surface of the layer of the third material. The layer of the fourth material can include a surface having cross-sectional profile including a plurality of portions corresponding to the portions of the cross-sectional profile of the surface of the layer of the first material.

The monolayers can be formed using atomic layer deposition.

The methods can include forming the layer of the first material by etching an intermediate layer of the first material.

The surface of the layer of the first material can have a periodic cross-sectional profile. In some embodiments, the surface of the layer of the first material has a saw-tooth cross-sectional profile.

Embodiments of the invention may include one or more of the following advantages.

In certain embodiments, the article is a grating that is relatively thick. As an example, in some embodiments, gratings can include multiple layers, which are sequentially formed on a substrate. A relatively thick grating can be made by forming a multilayer grating with a large plurality of layers or of one or more layers that are relatively thick.

In some embodiments, the article is a grating that is relatively robust. For example, a grating formed from numerous layers having a modulated (e.g., saw-tooth) surface profile can be a monolithic structure, and hence mechanically robust.

Furthermore, surfaces of the grating can be planar, for example, by filling in a modulated surface of a grating with a cap layer.

Gratings can be manufactured with relatively few process steps. For example, layers of a multilayer grating can be formed by depositing layers of one or more materials onto a modulated substrate surface, such as a surface of a layer having a saw-tooth profile. Where each deposited layer adopts the same profile as the underlying layer, additional layers can be deposited maintaining the grating structure without additional steps (e.g., without additional lithography steps).

Accordingly, in some embodiments, devices that include relatively thick retarders can be economically manufactured. As an example, form birefringent walk-off crystal devices can be manufactured relatively inexpensively.

Furthermore, characteristics of gratings can be easily controlled and manipulated. For example, utilizing manufacturing methods that allow precise control of features and composition of form birefringent layers allow one to control and manipulate the optical characteristics of the retarders (e.g., retardation and retardation as a function of wavelength). Examples of such manufacturing methods include lithographic techniques (e.g., photolithography, electron beam lithography, nano-imprint lithography) and deposition techniques (e.g., atomic layer deposition, vapor deposition, sputtering, evaporation). Other features and advantages will be apparent from the description and drawings, and from the claims.

### DESCRIPTION OF DRAWINGS

FIG. 1A is a cross-sectional view of an embodiment of a grating.

FIG. 1B is a cross-sectional view of a portion of the grating shown in FIG. 1A.

FIG. 2A is a cross-sectional view of another embodiment of a grating.

FIG. 2B is a cross-sectional view of another embodiment of a grating.

FIG. 3 is a cross-sectional view of another embodiment of a grating.

FIG. 4 is a cross-sectional view of another embodiment of a grating.

FIG. 5 is a cross-sectional view of another embodiment of a grating.

FIGS. 6A-6C are schematic diagrams showing steps in a method of fabricating of a grating.

FIGS. 7A and 7B are schematic diagrams showing alternative steps in a method of fabricating of a grating.

FIGS. 8A and 8B are schematic diagrams showing alternative steps in a method of fabricating of a grating.

FIGS. 9A-9C are schematic diagrams showing alternative steps in a method of fabricating of a grating.

FIG. 10 is a schematic diagram of a birefringent walk-off crystal including a grating.

FIG. 11 is a schematic diagram of a polarizer including a grating.

FIG. 12 is a schematic diagram of an optical pickup for reading/writing an optical storage medium.

Like reference symbols in the various drawings indicate like elements.

### DETAILED DESCRIPTION

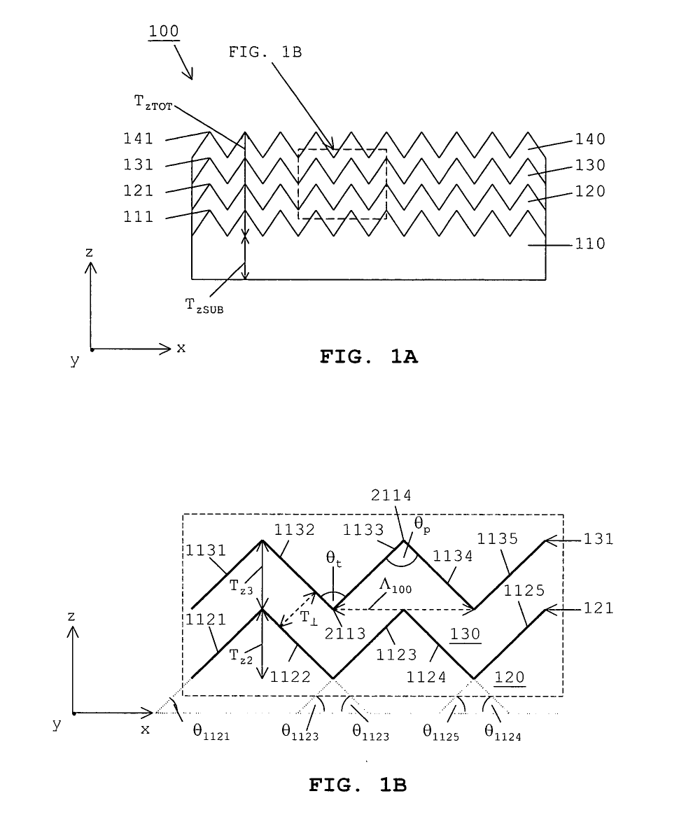

Referring to FIGS. 1A and 1B, a grating 100 includes a substrate 110 and three layers 120, 130, and 140 supported by substrate 110. A Cartesian co-ordinate system is provided for reference. Substrate 100 includes a surface 111 that is modulated along the x-direction, having a saw-tooth profile. Layer 120 is disposed on surface 111 and has a surface 121 with a saw-tooth profile. Layer 130 is disposed on surface 121, and layer 140 is disposed on surface 131 of layer 130. Both surface 131 and surface 141 of layer 140 have saw-tooth profiles. The saw-tooth profiles of surfaces 121, 131, 131, and 141 are substantially the same. Grating 100 extends parallel to the x-y plane.

Grating 100 interacts with incident radiation in a way that depends on the composition and structure of grating 100, and on the wavelength, angle of incidence, and polarization state of the incident radiation. Typically, grating 100 is designed to provide a certain optical effect for radiation having a wavelength λ (or wavelengths) incident on grating 100 from a particular direction. For example, grating 100 can diffract radiation at λ incident along a direction parallel to the z-axis. In some embodiments, grating 100 can retard orthogonal polarization states of radiation at λ propagating parallel to, e.g., the z-axis. As another example, in some embodiments, grating 100 can disperse radiation composed of a band of wavelengths incident thereon into its component wavelengths. Typically, λ is within the ultra-violet (e.g., from about 150 nm to about 400 nm), visible (e.g., from about 400 nm to about 700 nm), or infrared portions (e.g., from about 700 nm to about 12,000 nm) of the electromagnetic spectrum. Optical characteristics of grating 100, such as birefringence, absorption, and/or diffractive characteristics, are discussed below, after a description of structural and compositional features of grating 100.

Each surface 111, 121, 131, and 141 include a number of substantially parallel facets. Referring specifically to FIG. 1B, surface 121, for example, includes facets 1121-1125. Facets 1121, 1123, and 1125 are substantially parallel. Similarly, facets 1122 and 1124 are substantially parallel. Because surfaces 111, 121, 131, and 141 have substantially the same cross-sectional profile, each facet in one surface has a corresponding facet in the other surfaces. For example, facet 1122 in surface 121 has a corresponding facet 1132 in surface 131. Moreover, corresponding facets have substantially the same length in the x-z plane. For example, the length of a facet in surface 131 can be within about 10% or less of the length of the corresponding facet in surface 121 (e.g., within about 8% or less, about 7% or less, about 6% or less, about 5% or less, about 4% or less, about 3% or less, about 2% or less, about 1% or less).

Adjacent facets meet at peaks, e.g., peaks 1126, 1128, and troughs, e.g., troughs 1127, 1129.

Each facet intersects a plane parallel to the x-y plane at a facet angle, e.g., angles θ₁₁₂₁, θ₁₁₂₂, θ₁₁₂₃, θ₁₁₂₄, and θ₁₁₂₅ for facets 1121, 1122, 1123, 1124, and 1125, respectively. Substantially parallel facets have substantially the same facet angle. For example, the facet angle of a facet in surface 131 can be within about 10% or less of the length of the corresponding facet angle in surface 121 (e.g., within about 8% or less, about 7% or less, about 6% or less, about 5% or less, about 4% or less, about 3% or less, about 2% or less, about 1% or less). In some embodiments, a difference between corresponding facet angles in surfaces 121 and 131 can be about 5° or less (e.g., about 4° or less, about 3° or less, about 2° or less, about 1° or less, about 0.5° or less).

The facet angle of adjacent facets can be the same or different. In general, facet angles are selected based on the desired optical properties of grating 100 and can vary. In some embodiments, facet angles are about 60° or less (e.g., about 50° or less, about 45° or less, about 40° or less, about 30° or less, about 20° or less, about 15° or less, about 12° or less, about 10° or less).

Adjacent facets that intersect at a peak subtend a peak angle. For example, surface 131 includes adjacent facets 1133 and 1134 that subtend a peak angle, θₚ, at peak 2114. Similarly, adjacent facets that intersect at a trough subtend a trough angle, such as facets 1132 and 1133 of surface 131 which subtend a trough angle θₜ at trough 2113. In general, peak and trough angles depend on the profile of the surface and are selected based on desired optical characteristics of grating 100 and the methods used to form the grating (discussed below). While peak angles and trough angles are the same for each peak and trough in surfaces 111, 121, 131, and 141, in general, the peak angle for all peaks in a surface can be the same or different. Similarly, the trough angles for all troughs in a surface can be the same or different. In some embodiments, for example, where alternate facets in a surface are mutually parallel, the peak and trough angles of adjacent peaks and troughs are the same. In embodiments, peak angles and/or trough angles in a surface can be about 45° or more (e.g., about 70° or more, about 80° or more, about 90° or more, about 100° or more, about 110° or more, about 120° or more, about 130° or more).

As shown in FIG. 1B, surface 131 includes facets 1131, 1132, 1133, 1134, and 1135 that are parallel to facets 1121-1125, respectively. Accordingly, corresponding facets in each surface (e.g., facets 1121 and 1131) have the same facet angle. Furthermore, corresponding facets in surface 121 and 131 subtend the same respectively peak or trough angle. In grating 100, surfaces 111 and 141 include facets corresponding to the facets of surfaces 121 and 131. Corresponding facets in each layer are parallel.

The saw-tooth profile of each layer has a period Al₀₀, corresponding to the distance between adjacent troughs in a surface. For grating 100, each surface modulation of each surface has the same period. In some embodiments, however, the distance between adjacent troughs in a surface can vary.

Λ₁₀₀ is typically selected based on the desired optical characteristics of grating 100, and is typically about 10λ or less (e.g., about 5λ or less, about 2λ or less, about λ or less). Guidelines for selecting Λ₁₀₀ are discussed below. In some embodiments, Λ₁₀₀ is less than λ, such as about 0.5λ or less (e.g., about 0.3λ or less, about 0.2λ or less, about 0.1 λ or less, about 0.08λ or less, about 0.05λ or less, about 0.04λ or less, about 0.03λ or less, about 0.02× or less, 0.01λ or less). Alternatively, Λ₁₀₀ can be about equal to λ, or greater than 1 (e.g., about 1.1λ or more, about 1.2× or more, about 1.3× or more, about 1.4λ or more, about 1.5λ or more, about 1.8λ or more, about 2λ or more, about 3λ or more, about 5λ or more). In many applications, Λ₁₀₀ is about 10λ or less (e.g., about 8λ or less, about 6× or less). In some embodiments, Λ₁₀₀ is about 500 nm or less (e.g., about 300 nm or less, about 200 nm or less, about 100 nm or less, about 80 nm or less, about 60 m or less, about 50 nm or less, about 40 nm or less). In certain embodiments, Λ₁₀₀ is between about 500 nm and 5,000 nm (e.g., about 600 nm or more, about 700 nm or more, about 800 nm or more, about 900 nm or more, about 1,000 or more, about 1,000 nm or more, about 1,200 nm or more, about 1,500 nm or more, about 2,000 nm or more, such as about 5,000 or less, about 4,000 nm or less, about 3,000 or less).

For surfaces 111, 121, 131, and 141, the distance from a trough to an adjacent peak measured along the z-axis is referred to as the modulation amplitude. The modulation amplitude is selected based on the desired optical characteristics of grating 100. In some embodiments, the modulation amplitude of a surface can be about five λ or less (e.g., about 3λ or less, about 2λ or less, about 1.5λ or less, about λ or less, about 0.8× or less, about 0.7λ or less, about 0.5 λ or less, about 0.3λ or less, about 0.2λ or less, about 0.1λ or less, such as about 0.05λ or less). In certain embodiments, the modulation amplitude of a surface can be about 5,000 nm or less (e.g., about 3,000 nm or less, about 2,000 nm or less, about 1,500 nm or less, about 1,000 nm or less, about 800 nm or less, about 600 nm or less, about 500 nm or less, about 400 nm or less, about 300 nm or less, about 200 nm or less, about 150 nm or less, about 100 nm or less).

Moreover, while modulations in surfaces 111, 121, 131, and 141 have the same amplitude as the other modulations in each surface, more generally, the amplitude of each modulation in a surface can vary.

The thickness of each layer 120, 130, and 140 can be characterized by the layer's thickness as measured along the z-axis, referred to as the layer's z-thickness, and/or by a perpendicular thickness, which is the thickness or a layer measured along a direction perpendicular to a facet.

The z-thickness, shown as T_{z2} and T_{z3} for layers 120 and 130 in FIG. 1B, respectively, can be measured as the distance from the peak of one surface to the corresponding peak in the surface of the adjacent layer. For example, T_{z3} corresponds to the distance between a peak in surface 121 and a corresponding peak in surface 131. In general, the z-thickness of each layer can vary. Typically, the z-thickness of each layer is selected based on desired optical characteristics of grating 100. The z-thickness of one of layers 120-140 can be the same or different as the thickness of the other layers. The z-thickness of a layer can be the same as or different from the modulation amplitude of the layer's surface. In general T_{zi} (where i=2, 3, or 4, corresponding to layers 120, 130 and 140, respectively) can be less than or greater than λ. For example, T_{zi} can be about 0.1λ or more (e.g., about 0.2λ or more, about 0.3× or more, about 0.5λ or more, about 0.8λ or more, about λ or more, about 1.5λ or more, such as about two λ or more). In certain embodiments, T_{zi} can be about 50 nm or more (e.g., about 75 nm or more, about 100 nm or more, about 125 nm or more, about 150 nm or more, about 200 nm or more, about 250 nm or more, about 300 nm or more, about 400 m or more, about 500 nm or more, about 750 nm or more, such as about 1,000 nm).

Substrate 110 has a z-thickness corresponding to the modulation amplitude of surface 111, which can be the same or different as the z-thickness of one or more of layers 120, 130, or 140. The thickness of substrate 110 from the surface opposite to surface 111 to the nearest trough in surface 111, measured along the z-axis, is referred to as T_{zSUB}. Typically, T_{zSUB} is sufficiently large so that substrate 110 provides mechanical support for layers 120, 130, and 140. In some embodiments, T_{zSUB} can be about 100 μm or more (e.g., about 200 μm or more, about 300 μm or more, about 400 μm or more, about 500 μm or more, about 800 μm or more, about 1,000 μm or more, about 5,000 μm or more, about 10,000 μm or more).

The perpendicular thickness, T_{⊥}, of each layer can also vary. For example, T_{⊥} can be about 0.1λ or more (e.g., about 0.2 λ or more, about 0.3λ or more, about 0.5λ or more, about 0.8 λ or more, about λ or more, about 1.5λ or more, such as about 2λ or more). In certain embodiments, T_{⊥} can be about 50 nm or more (e.g., about 75 nm or more, about 100 nm or more, about 125 nm or more, about 150 nm or more, about 200 nm or more, about 250 nm or more, about 300 nm or more, about 400 nm or more, about 500 nm or more, about 750 nm or more, such as about 1,000 nm).

Grating 100 has a total z-thickness of T_{zTOT}, which corresponds to the lowest point on surface 111 to the highest point on surface 141 as measured along the z-axis. In general, T_{zTOT} depends on the peak-to-trough modulation amplitude of surfaces 121 and 141, and the thickness of layers 120, 130, and 140 measured along the z-axis. T_{zTOT} is typically selected so that grating 100 has desired optical characteristics. In some embodiments, T_{zTOT} can be relatively small compared to a wavelength or wavelengths of interest. For example, T_{zTOT} can be about 0.1λ or less (e.g., 0.2λ or less, 0.3λ or less, 0.5λ or less, 0.6λ or less). Alternatively, in certain embodiments, T_{zTOT} can be large compared to λ, (e.g., about five λ or more, about five λ or more, about 10λ or more, about 15λ or more, about 20λ or more). In further embodiments, T_{zTOT} can be comparable to λ (e.g., from about 0.8 λ to about two λ, from about λ to about 1.5 λ).

In some embodiments, T_{zTOT} is about 100 nm or more (e.g., about 200 nm or more, about 500 nm or more, about 800 nm or more, about 1,000 nm or more, about 1,500 or more, about 2,000 or more, about 3,000 nm or more, about 5,000 or more, such as about 8,000 or more). T_{zTOT} can be about 100,000 nm or less, about 50,000 nm or less, about 30,000 nm or less, about 20,000 nm or less, about 15,000 nm or less, about 12,000 nm or less, about 10,000 nm or less).

The aspect ratio of T_{zTOT} to Λ₁₀₀ can be relatively high. For example T_{zTOT}:Λ₁₀₀ can be about 2:1 or more (e.g., about 3:1 or more, about 4:1 or more, about 5:1 or more, about 8:1 or more, about 10:1 or more).

In general, the refractive indexes of adjacent layers and the layer adjacent the substrate at λ are different. In other words, the refractive index of substrate 110 at λ is different from the refractive index of layer 120, and the refractive index of layer 130 is different from the refractive index of layers 120 and 140. The difference between the refractive indexes of adjacent layers is referred to as the refractive index mismatch between those layers. In general, the refractive index mismatch between adjacent layers can vary, and depends upon the desired optical characteristics of grating 100. In some embodiments, the refractive index mismatch can be relatively small (e.g., about 0.05 or less, about 0.03 or less, about 0.02 or less, about 0.01 or less, about 0.05 or less). In certain embodiments, the refractive index mismatch can be large (e.g., about 0.1 or more, about 0.15 or more, about 0.2 or more, about 0.25 or more). The refractive index mismatch between adjacent layers can be between 0.05 and 0.1 (e.g., about 0.06, about 0.07, about 0.08, about 0.09).

In some embodiments, at least some of layers 120, 130, 140, and/or substrate 110 have a relatively high refractive index. For example, one or more layers 120, 130, 140, and/or substrate 110 can have a refractive index of about 1.8 or more (e.g., about 1.9 or more, about 2.0 or more, about 2.1 or more, about 2.2 or more, about 2.3 or more). Alternatively, or additionally, one or more layers and/or substrate 110 can have a relatively low refractive index (e.g., about 1.7 or less, about 1.6 or less, about 1.5 or less). In certain embodiments, substrate 110 and layers 120, 130, and 140 alternative between relatively high and relatively low refractive indexes.

In general, the materials forming substrate 110 and layers 120, 130, and 140 are selected based on their optical properties (e.g., their refractive index and absorption at λ), their compatibility with each other, and their compatibility with manufacturing processes used to form the layers.

Substrate 110 and/or layers 120, 130, and 140 can include inorganic and/or organic materials. Examples of inorganic materials include metals, semiconductors, and inorganic dielectric materials (e.g., glass, SiNₓ). Examples of organic materials include polymers.

In some embodiments, substrate 110 and/or layers 120, 130, and 140 include one or more dielectric materials, such as dielectric oxides (e.g., metal oxides), fluorides (e.g., metal fluorides), sulphides, and/or nitrides (e.g., metal nitrides). Examples of oxides include SiO₂, Al₂O₃, Nb₂O₅, TiO₂, ZrO₂, HfO₂, SnO₂, ZnO, ErO₂, Sc₂O₃, and Ta₂O₅. Examples of fluorides include MgF₂. Other examples include ZnS, SiNₓ, SiO_{y}Nₓ, AlN, TiN, and HfN.

Substrate 110 and/or layers 120, 130, and 140 can be formed from a single material or from multiple different materials (e.g., composite materials, such as nanocomposite materials).

Substrate 110 and/or layers 120, 130, and 140 can include crystalline, semi-crystalline, and/or amorphous portions. Typically, an amorphous material is optically isotropic and may transmit radiation better than portions that are partially or mostly crystalline. As an example, in some embodiments, both substrate 110 and layers 120, 130, and 140 are formed from amorphous materials, such as amorphous dielectric materials (e.g., amorphous TiO₂ or SiO₂). Alternatively, in certain embodiments, some of layers 120, 130, and 140 and/or substrate 110 are formed from a crystalline or semi-crystalline material (e.g., crystalline or semi-crystalline Si), while the other layers/substrate are formed from an amorphous material (e.g., an amorphous dielectric material, such as TiO₂ or SiO₂).

In certain embodiments, substrate 110 is formed from a glass, such as a borosilicate glass. As an example, in some embodiments, substrate 110 is formed from S-BSL7, a glass commercially available from Ohara Incorporated (Kanagawa, Japan). S-BSL7 has a refractive index of 1.516 at 587.56 nm.

As discussed previously, in some embodiments, one or more of substrate 110 and/or layers 120, 130, and 140 can have a relatively high refractive index. Examples of materials with a relatively high refractive index include TiO₂, which has a refractive index of about 2.35 at 632 nm, or Ta₂O₅, which has a refractive index of 2.15 at 632 nm.

Moreover, low index materials such as MgF₂, SiO₂ and Al₂O₃, which have refractive indexes of about 1.37, 1.45 and 1.65 at 632 nm, respectively, can be used where one or more of substrate 110 and/or layers 120, 130, and 140 have a relatively low refractive index. Various polymers can also have a relatively low refractive index (e.g., from about 1.4 to about 1.7).

In some embodiments, the materials forming substrate 110 and/or layers 120, 130, and 140 have a relatively low absorption at λ, so that grating 100 has a relatively low absorption at those wavelengths. For example, grating 100 can absorb about 5% or less of radiation at wavelengths in the range Δλ propagating along the z-axis (e.g., about 3% or less, about 2% or less, about 1% or less, about 0.5% or less, about 0.2% or less, about 0.1% or less).

Due to the modulation in surfaces 111, 121, 131, and 141, an effective refractive index of grating 100 at is modulated in the x-direction. The effective refractive index, n_{eff}, is proportional to the phase shift, φ, experienced by radiation at λ propagating through grating 100 along a path parallel to the z-axis, and is given by

$${n}_{eff} ( x ) = \frac{ϕ ( x ) λ}{2 π {T}_{zTOT}} . \qquad ( 1 )$$

The variation of n_{eff} and φ in the x-direction are expressed as a functional dependence of n_{eff} and φ on x in Eq. (1). Note also that n_{eff}(x) can depend on the polarization state of the incident light.

In some embodiments, effective media theory (EMT) can be used to determine the approximate phase of radiation at various wavelengths that traverses grating 100. For example, in embodiments where Λ₁₀₀ is less than λ, EMT provides a useful tool for evaluating the optical performance of grating 100 for different values of parameters associated with grating 100's structure. Implementations of EMT are described, for example, by H. Kikuta et al., in “Achromatic quarter-wave plates using the dispersion of form birefringence,” Applied Optics, Vol. 36, No. 7, pp. 1566-1572 (1997), by C.W. Haggans et al., in “Effective-medium theory of zeroth order lamellar gratings in conical mountings,” J. Opt. Soc. Am. A, Vol. 10, pp 2217-2225 (1993), and by H. Kikuta et al., in “Ability and limitations of effective medium theory for subwavelength gratings,” Opt. Rev., Vol. 2, pp. 92-99 (1995).

Generally, in EMT, a sub-wavelength grating is considered to be an anisotropic thin film with effective refractive indexes. The phase retardation for light propagating through the film can be determined from the film thickness and the difference between the effective refractive indexes. EMT provides an approximate value of the phase of light waves that have passed through the grating.

Due to the sawtooth structure of grating 100, for the purposes of EMT, the grating is considered to be formed from a number of anisotropic thin film sections, each having a periodic structure with a fixed period. However, the duty cycle of each thin film section varies depending on the location of the section along the z-axis. The phase retardation for light propagating through grating 100 can then be determined as the total phase change experienced by the light propagating through all the thin film sections.

Furthermore, by considering the phase change at different wavelengths, EMT can be used to determine the wavelength dependence of grating 100.

In some embodiments, grating 100 is form birefringent for radiation having wavelengths of λ or higher. In other words, different polarization states of radiation having wavelength λ propagate through grating 100 with different phase shifts, which depend on the total z-thickness of grating 100, the indexes of refraction of substrate 110 and layers 120, 130, and 140, the respective z-thickness (and/or perpendicular thickness) of layers 120, 130, and 140, the amplitude modulation of substrate 110 and layers 120, 130, and 140, and the modulation period, Λ₁₀₀. Accordingly, these parameters can be selected to provide a desired amount of retardation to polarized light at a wavelength λ.

Grating 100 has a birefringence, Δn(λ), at wavelength λ, which corresponds to nₑ-nₒ, where nₑ and nₒ are the effective extraordinary and effective ordinary indexes of refraction for grating 110, respectively. The effective extraordinary index of refraction is the index of refraction experienced by radiation having its electric field polarized along the x-direction, while the effective ordinary index is the index of refraction experienced by radiation having its electric polarized along the y-direction. In general, the values of nₑ and nₒ depend on the indexes of refraction of substrate 110 and layers 120, 130, and 140, the respective z-thickness (and/or perpendicular thickness) of layers 120, 130, and 140, the amplitude modulation of substrate 110 and layers 120, 130, and 140, and the modulation period, Λ₁₀₀. In some embodiments, Δn is relatively large (e.g., about 0.1 or more, about 0.15 or more, about 0.2 or more, about 0.3 or more, about 0.5 or more, about 1.0 or more, about 1.5 or more, about 2.0 or more). A relatively large birefringence can be desirable in embodiments where a high retardation and/or phase retardation are desired (see below), or where a thin grating is desired. Alternatively, in other embodiments, Δn is relatively small (e.g., about 0.05 or less, about 0.04 or less, about 0.03 or less, about 0.02 or less, about 0.01 or less, about 0.005 or less, about 0.002 or less, 0.001 or less). A relatively small birefringence may be desirable in embodiments where a low retardation or phase retardation are desired, and/or where relatively low sensitivity of the retardation and/or phase retardation to variations in the thickness of grating 110 is desired.

The retardation of grating 100 is the product of the total z-thickness of grating 100, T_{zTOT}, and Δn. By selecting appropriate values for Δn and the T_{zTOT}, the retardation can vary as desired. In some embodiments, the retardation of grating 100 is about 50 nm or more (e.g., about 75 nm or more, about 100 nm or more, about 125 nm or more, about 150 nm or more, about 200 nm or more, about 250 nm or more, about 300 nm or more, about 400 nm or more, about 500 nm or more, about 1,000 or more, such as about 2,000 nm). Alternatively, in other embodiments, the retardation is about 40 nm or less (e.g., about 30 nm or less, about 20 nm or less, about 10 nm or less, about 5 nm or less, about 2 nm or less). In some embodiments, the retardation corresponds to λ/4 or λ/2.

Grating 100 also has a phase retardation, Γ, for each wavelength, which can be approximately determined according to

$$Γ ( λ ) \approx \frac{2 π}{λ} \cdot Δ {n}_{eff} ( λ ) \cdot {T}_{zTOT} . \qquad ( 2 )$$

Quarter wave phase retardation is given, for example, by Γ=π/2, while half wave phase retardation is given by Γ=π. In general, phase retardation may vary as desired, and is generally selected based on the end use application of grating 100. In some embodiments, phase retardation may be about 2π less (e.g., about π less, about 0.8π or less, about 0.7π less, about 0.6π less, about 0.5π or less, about 0.4π or less, about 0.2π for less, 0.2π for less, about 0.1π or less, about 0.05 π or less, 0.01π or less).

Alternatively, in other embodiments, phase retardation of retardation layer 110 can be more than 2π (e.g., about 3π or more, about 4π or more, about 5π or more).

In some embodiments, grating 100 can be designed to diffract light at λ. For radiation incident on grating 100 at an angle θ₁ with respect to the z-axis, diffraction maxima occur at angles θₘ given approximated by the grating equation:
Λ₁₀₀(sin θₘ−sin θ₁)=mλ (3)
where m is an integer. Accordingly, by selecting appropriate values for Λ₁₀₀, grating 100 can be tailored to provide desired dispersion characteristics at λ. Typically, for diffraction gratings, Λ₁₀₀ is about λ or greater (e.g., about 1.5 λ or greater, about two λ or greater, about three λ or greater, about four λ or greater, about five λ or greater, about eight λ or greater, about 10λ or greater).

In certain embodiments, grating 100 can be designed to disperse radiation of different wavelengths incident on grating 100 into the constituent wavelengths.

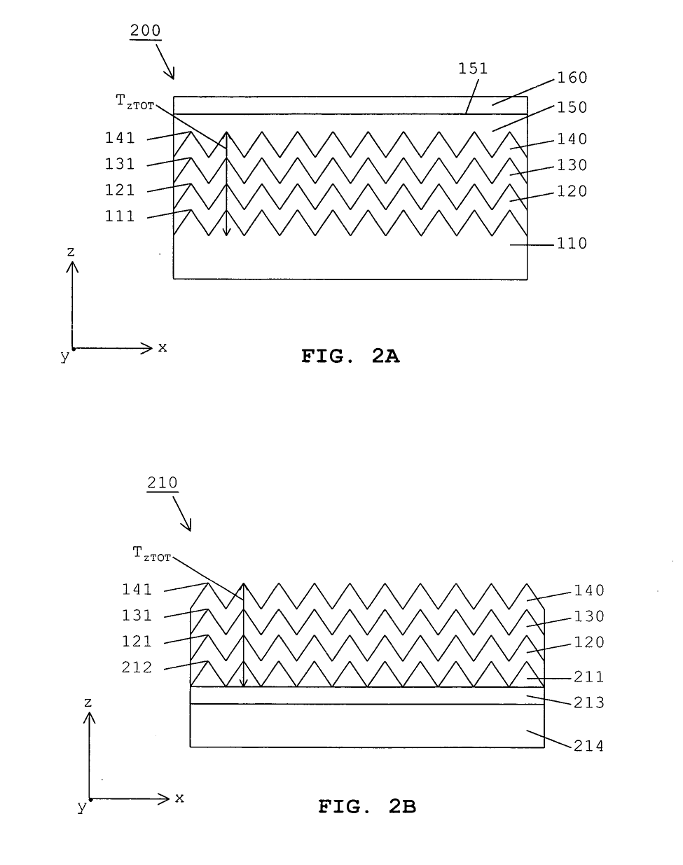

While grating 100 is composed of a substrate and three layers supported by the substrate, in general, gratings can include one or more additional layers. For example, referring to FIG. 2A, a grating 200 can include a cap layer 150 deposited on surface 141. Cap layer 150 fills in the troughs in surface 141 and provides a smooth surface 141 onto which one or more additional layers can be deposited.

In general, the thickness along the z-direction and composition of cap layer 140 can vary as desired, and are typically selected so that the layer provides its mechanical function without substantially adversely affecting the optical performance of grating 200 100. In some embodiments, cap layer 150 is about 50 nm or more thick (e.g., about 70 nm or more, about 100 nm or more, about 150 nm or more, about 300 nm or more thick). Cap layer can be formed from dielectric materials, such as dielectric oxides (e.g., metal oxides), fluorides (e.g., metal fluorides), sulphides, and/or nitrides (e.g., metal nitrides), such as those listed above.

Gratings can also include one or more optical films. For example, grating 200 includes an antireflection film deposited on surface 151 of cap layer 150. Antireflection film 160 can reduce the reflectance of radiation at one or more wavelengths of interest impinging on and exiting grating 100. Antireflection film 160 generally includes one or more layers of different refractive index. As an example, antireflection film 160 can be formed from four alternating high and low index layers. The high index layers can be formed from TiO₂ or Ta₂O₅ and the low index layers can be formed from SiO₂ or MgF₂. The antireflection films can be broadband antireflection films or narrowband antireflection films, with reflectance minima at or near λ.

In some embodiments, grating 200 has a reflectance of about 5% or less of light impinging thereon at wavelength λ (e.g., about 3% or less, about 2% or less, about 1% or less, about 0.5% or less, about 0.2% or less). Furthermore, grating 200 can have high transmission of radiation at λ. For example, grating 200 can transmit about 95% or more of light impinging thereon at λ (e.g., about 96% or more, about 97% or more, about 98% or more, about 99% or more, about 99.5% or more).

In certain embodiments, substrate 110 can be a composite substrate, including multiple layers of different materials. For example, referring to FIG. 2B, a grating 210 includes a planar substrate layer 214, an etch stop layer 213, and an additional layer with a saw-tooth profile supporting layers 120, 130, and 140.

Planar substrate layer 214 can be formed from any material compatible with the manufacturing processes used to produce grating 210 that can support the other layers. In certain embodiments, planar substrate layer 214 is formed from a glass, such as BK7 (available from Abrisa Corporation), borosilicate glass (e.g., pyrex available from Corning), aluminosilicate glass (e.g., C1737 available from Corning), or quartz/fused silica. In some embodiments, planar substrate layer 214 can be formed from a crystalline material, such as a non-linear optical crystal (e.g., LiNbO₃ or a magneto-optical rotator, such as garnett) or a crystalline (or semicrystalline) semiconductor (e.g., Si, InP, or GaAs). Planar substrate layer 214 can also be formed from an inorganic material, such as a polymer (e.g., a plastic). Substrate layers can also be a metal or metal-coated substrate.

Etch stop layer 213 is formed from a material resistant to etching processes used to etch the material(s) from layer 211 is formed. The material(s) forming etch stop layer 213 should also be compatible with planar substrate layer 214 and with the materials forming layer 211. Examples of materials that can form etch stop layer 213 include HfO₂, SiO₂, Al₂O₃, Ta₂O₅, TiO₂, SiNₓ, or metals (e.g., Cr, Ti, Ni).

The thickness of etch stop layer 213 in the z-direction can vary as desired. Typically, etch stop layer 213 is sufficiently thick to prevent significant etching of planar substrate layer 211, but should not be so thick as to adversely impact the optical performance of grating 210. In some embodiments, etch stop layer is about 500 nm or less thick (e.g., about 250 nm or less, about 100 nm or less, about 75 nm or less, about 50 nm or less, about 40 nm or less, about 30 nm or less, about 20 nm or less).

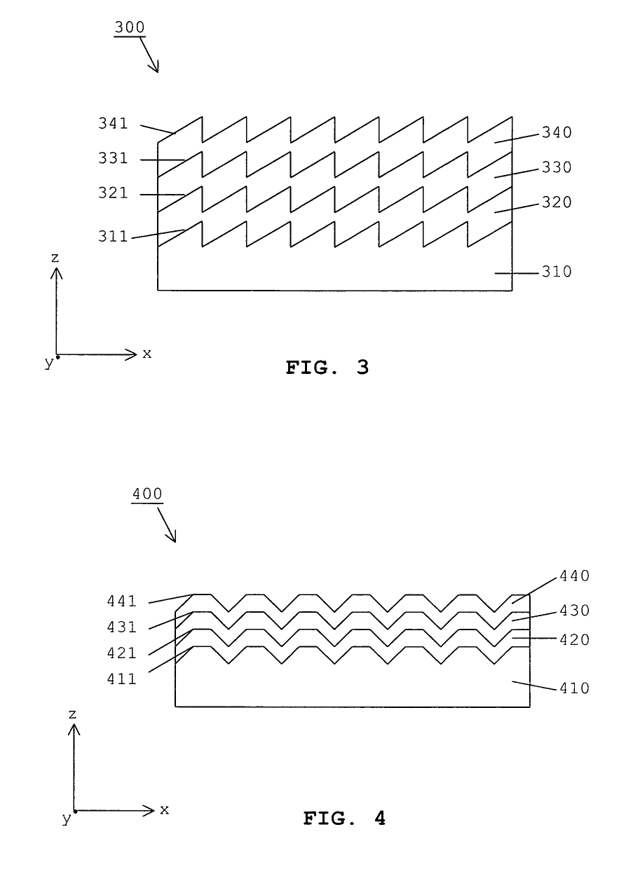

While the grating surface profile layers described previously have saw-tooth profiles, in general, the profile of grating layer surfaces can have other shapes. Referring to FIG. 3A, as an example of a grating with layer surfaces having a different saw-tooth profile, a grating 300 can include a substrate 310 and layers 320, 330, and 340 that have a saw-tooth profile including facets with a facet angle of about 90°.

An example of a grating having layers with a surface profile different from a saw-tooth profile is shown in FIG. 4. Grating 400 includes a substrate 410 and layers 420, 430, and 440. Surfaces 411, 421, 431, and 441 of substrate 410 and layers 420, 430, and 440 have a modulation with a trapezoidal profile.

Another example of a grating having layers with a different surface profile is shown in FIG. 5. Grating 500 includes a substrate 510 and layers 520, 530, and 540. Surfaces 511, 521, 531, and 541 of substrate 510 and layers 520, 530, and 540 have a modulation with a rectangular profile.

While modulations in the layer surface profiles of gratings described above are periodic, in general, the modulation can vary as desired. For example, the modulation can be random, quasi-periodic, or periodic. In some embodiments, the modulation of a grating layer surface can be chirped or varied with a period substantially larger than the modulation period.

The number of modulations in a grating can vary, depending on A and the desired area for the grating. Typically, each modulated grating layer will include about 10 or more modulations (e.g., about 20 or more modulations, about 50 or more modulations). In some embodiments, a grating can include modulated layers with several hundred or thousands of modulations (e.g., about 1,000 or more modulations, about 5,000 or more modulations, about 10,000 or more modulations).

Furthermore, while the gratings described above each have three layers with modulated surfaces supported by a substrate, in general, gratings can have fewer or more than three layers with modulated surfaces. The number of layers can be selected based on desired optical properties of each grating. For example, the number of layers can be selected so that a grating has a certain retardation at λ, or certain diffractive properties at λ. In some embodiments, a grating can include about five or more layers with a modulated surface (e.g., about six or more layers, about seven or more layers, about eight or more layers, about nine or more layers, about 10 or more layers, about 12 or more layers, about 15 or more layers, about 20 or more layers, about 30 or more layers, about 50 or more layers).

While layers in the gratings discussed previously have surfaces modulated in one direction only (i.e., the x-direction), in general, gratings can include layers having surface modulations in more than one direction. For example, in some embodiments, gratings can include layer surfaces modulated in the y-direction as well as the x-direction. Generally, the modulation amplitude and period in each direction can be the same or different.

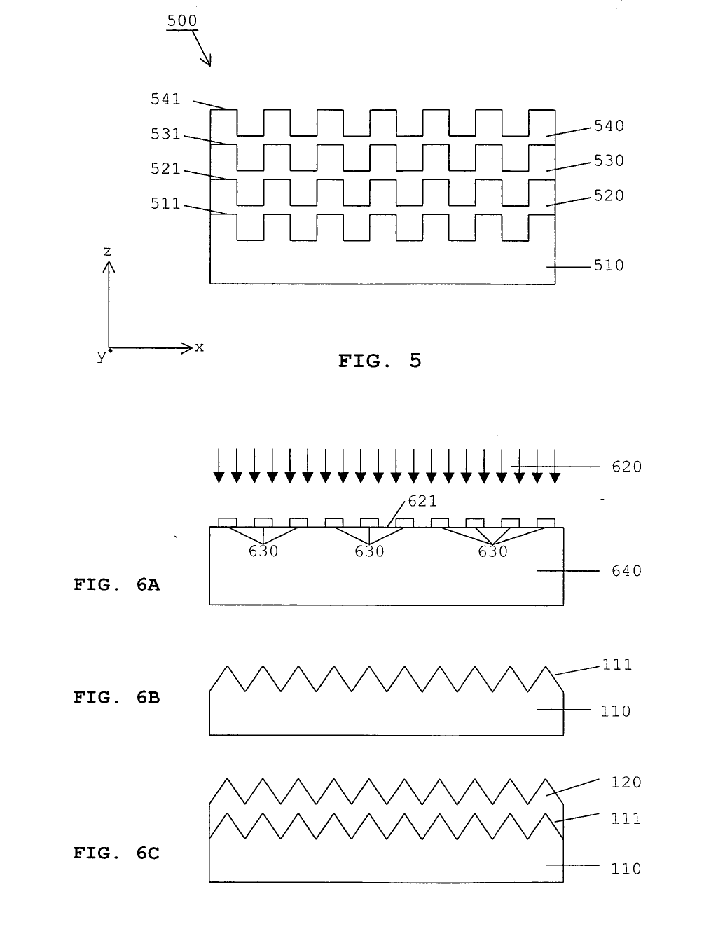

In general, gratings described herein can be formed using a variety of methods. For example, gratings can be formed using methods commonly used to fabricate microelectronic components, including a variety of deposition and lithographic patterning techniques. Steps of an exemplary process for forming grating 100 are shown in FIG. 6A-6C. Referring specifically to FIG. 6A, initially, a layer 640 of a substrate material is provided and a patterned layer of resist is deposited on a surface 621 of layer 640. The patterned resist includes a number of portions periodically spaced in the x-direction. The spacing between different portions 630 of the patterned resist corresponds to the period, Λ₁₀₀, of grating 100.

Portions 630 of resist can be formed by depositing a continuous layer of resist onto surface 621 and using electron beam lithography or photolithograpy (e.g., using a photomask or using holographic techniques) and a subsequent etching step to pattern the continuous resist layer. In some embodiments, portions 630 are formed using nano-imprint lithography, which includes forming a continuous layer of a resist on surface 621, and impressing a pattern into the continuous resist layer using a mold. The resist can be polymethylmethacrylate (PMMA) or polystyrene, for example. The patterned resist layer includes thin portions and thick portions. Subsequent etching of the impressed layer (e.g., by oxygen reactive ion etching (RIE)) removes the thin portions of the resist, leaving behind portions 630 that correspond to the thick portions.

Exposed portions of surface 621 are etched by exposing surface 621 to an etchant 620. The etch method, etchant, resist type and thickness, and width of resist portions in the x-direction are selected so that the etching provides the desired surface profile in a layer of the substrate material. As an example, a dry etch (e.g., RIE) can be used to etch exposed portions of an S-BSL7 glass substrate. The etchant can be CHF₃/O₂, used with a polymer resist with obliquely deposited Cr. Etching should be of sufficient duration at sufficient power to provide the desired surface profile for surface 111. In some embodiments, etching takes between about five minutes and one hour, such as between about 20 to 30 minutes. As an example, a S-BSL7 layer can be etched using a 720 machine obtained from Plasmatherm, with gas pressure of about 4 mTorr, CHF₃ at 10 sccm, O₂ at 1 sccm, and at a power of 100 W.

In some embodiments, where layer 640 is formed from a crystalline material, the orientation of the crystalline lattice can influence the resulting shape of the etched surface. For example, a crystalline Si layer with the [110] axis oriented normal to surface 621, masked with SiO₂, can be wet etched (e.g., using KOH) to provide a saw-tooth profile.

Referring to FIG. 6B, after etching, portions of surface 621 are removed, thereby providing surface 111 on substrate 110. Referring to FIG. 6C, next, layer 120 is deposited on surface 111 using a conformal deposition method, such as atomic layer deposition, for example. During ALD, deposition of a layer of material occurs monolayer-by-monolayer, providing substantial control over the composition and thickness of the layer. During deposition of a monolayer, vapors of a precursor are introduced into the chamber and are adsorbed onto substrate surface 111 or previously deposited layers adjacent the surface. Subsequently, a reactant is introduced into the chamber that reacts chemically with the adsorbed precursor, forming a monolayer of a desired material. The self-limiting nature of the chemical reaction on the surface can provide precise control of film thickness and large-area uniformity of the deposited layer. Moreover, the non-directional adsorption of precursor onto exposed surfaces provides for uniform deposition of material onto surfaces having different orientations relative to the x-y plane. Atomic layer deposition is described in, for example, U.S. patent application Ser. No. 10/842,869, entitled “FILMS FOR OPTICAL USE AND METHODS OF MAKING SUCH FILMS,” filed on May 10, 2004, the entire contents of which are hereby incorporated by reference.

Conformal deposition methods, such as ALD, can be used to deposit layer 130 onto surface 121 of layer 120, and layer 140 onto surface 131 of layer 130.

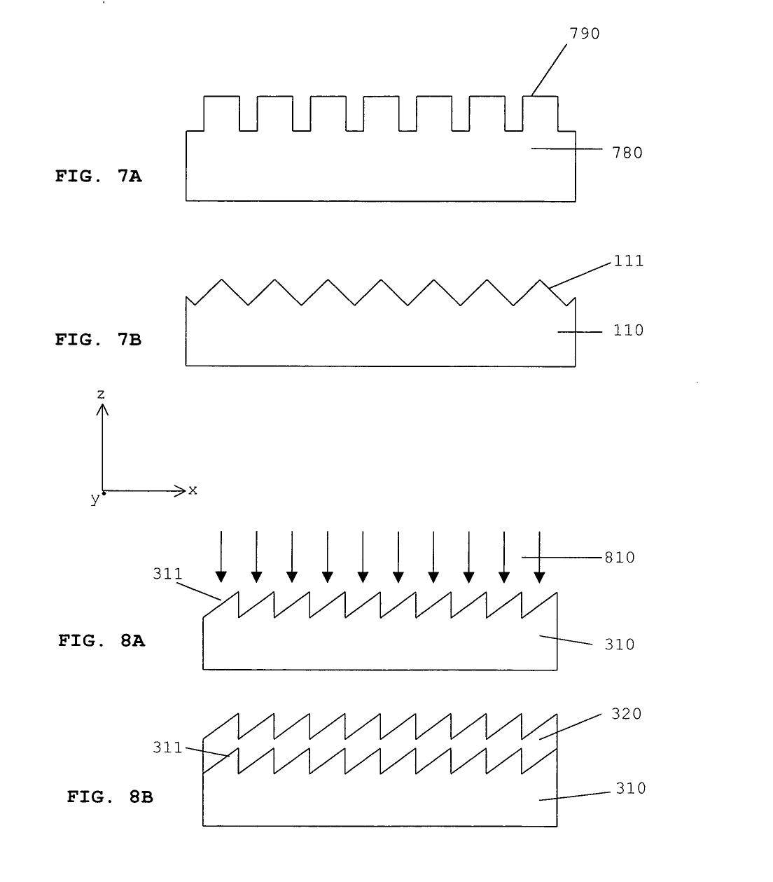

Other methods can also be used to provide a saw-tooth surface profile in a layer of material. For example, referring to FIGS. 7A and 7B, in some embodiments, a layer 780 with a surface 790 having a rectangular profile can be etched to form a saw-tooth surface profile.

In some embodiments, directional deposition methods may be used to form layers with substantially identical surface profiles as an underlying layer. For example, referring to FIGS. 8A and 8B, in some embodiments, non-conformal deposition techniques can be used to form layers having a modulated surface in a grating. A directional deposition technique can be used to deposit material onto one set of facets of surface 311 of substrate 310 can be used. Examples of such deposition techniques include evaporation techniques, such as electron beam evaporation. Due to the directional nature of the deposition technique, the exposed facets occlude the non-exposed facets, preventing direct deposition of material thereon. As the material builds on the exposed facets, it covers the occluded facets.

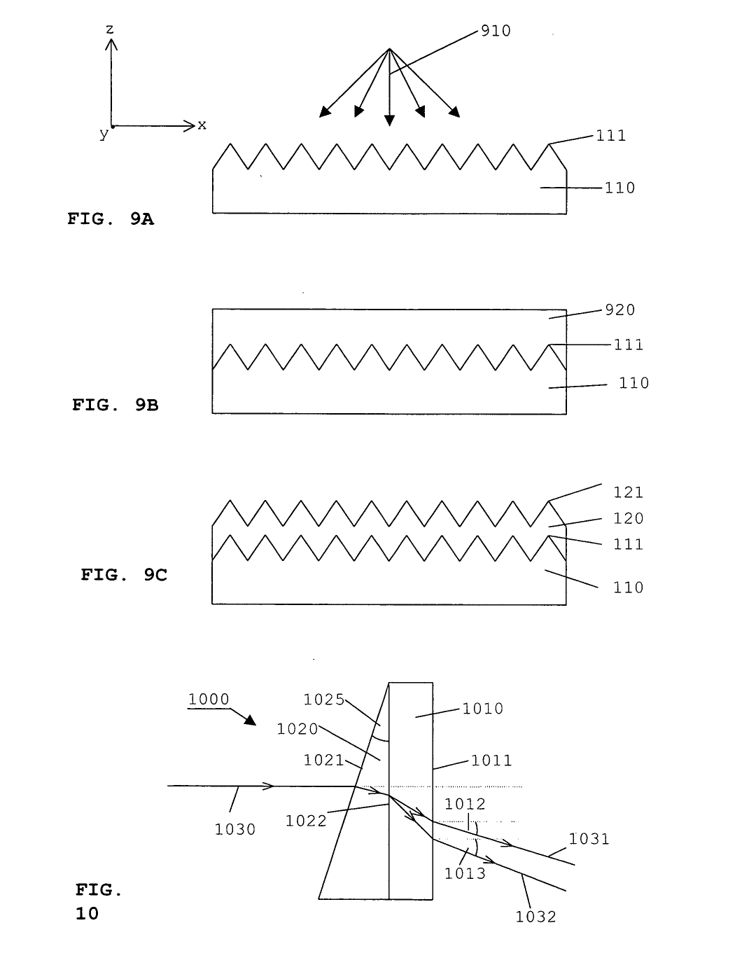

In some embodiments, lithographic techniques can be used to form more than one layer with a modulated surface in a grating. For example, referring to FIGS. 9A-9C, a non-conformal deposition technique (e.g., sputtering) can be used to deposit material 910 on surface 111 of substrate 110, forming a substantially planar layer 920. Planar layer 920 is then lithographically exposed and etched to provide layer 120 having surface 121 with a saw-tooth profile.

In general, gratings can be used in a variety of applications in which polarized light is manipulated. In some embodiments, an optical retarder can be combined with one or more additional optical components to provide an optical device. For example, optical retarders can be incorporated onto other optical components (e.g., a reflector, a filter, a polarizer, a beamsplitter, a lens, and/or an electro-optic or magneto-optic component) by forming one or more grating layers on a surface of the component.

Referring to FIG. 10, in certain embodiments, a grating 1010 can be used in a birefringent walk-off crystal 1000. In addition to grating 1010, walk-off crystal 1000 includes a wedge prism 1025, having a wedge angle 1025. A beam of radiation 1030 propagating along an optical axis is refracted at surface 1021 of prism 1020. The radiation is refracted again at surface 1022 of grating 1010. Grating 1010 is form birefringent for radiation at wavelength λ. Accordingly, radiation of orthogonal polarization states are refracted by different amounts and, and are directed along different paths. Accordingly, two beams of orthogonal polarization, beams 1031 and 1032, exit walk off crystal 1000. Beams 1031 and 1032 propagate along paths at angles 1012 and 1013 relative to the optical axis, respectively. The divergence of beams 1031 and 1032 corresponds to the difference between angles 1013 and 1012, and depends on wedge angle 1025, and the refractive indexes of prism 1020 and grating 1010. The separation of beams 1031 and 1032 depends on the thickness of grating 1010, with thicker gratings leading to increased separation. In some embodiments, walk-off crystal 1000 can be designed to operate at wavelengths typically used in telecommunications systems, such as from about 900 nm to about 1,100 nm or from about 1,300 nm to about 1,600 nm.

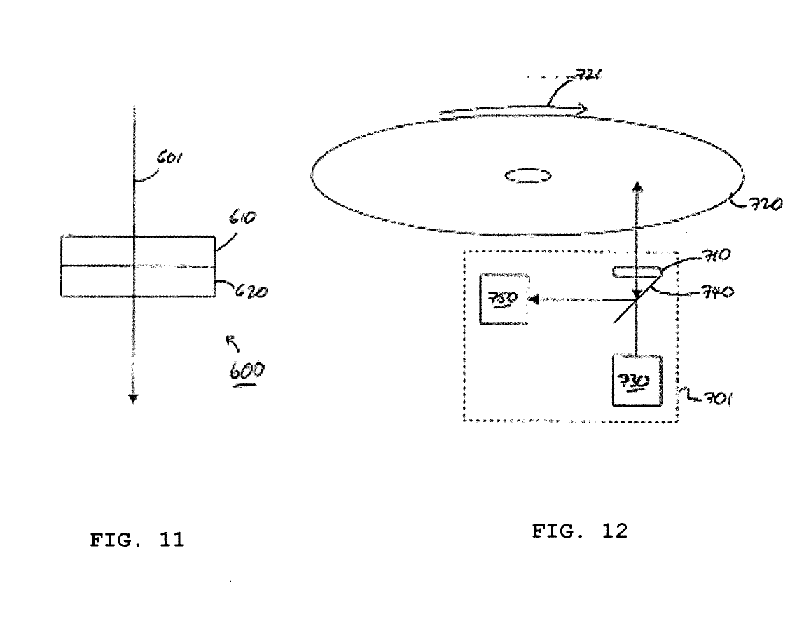

In some embodiments, a retardation film can be combined with a linear polarizing film to provide a polarizer that delivers light of a certain non-linear polarization (e.g., circularly polarized light or a specific elliptical polarization state). An example of such a device is polarizer 600, shown in FIG. 11. Polarizer 600 includes polarizing film 610 (e.g., an absorptive polarizing film, such as iodine-stained polyvinyl alcohol, or a reflective polarizer) and optical retarder 620. Film 610 linearly polarizes incident isotropic light propagating along axis 610. Subsequently, optical retarder 620 retards the polarized light exiting polarizing film 610, resulting in polarized light having a specific ellipticity and orientation of the elliptical axes. Alternatively, optical retarder 620 can be designed to rotate the electric field direction of the linearly polarized light exiting film 610. Polarizer 600 can be included in a variety of optical systems, such as, for example, a liquid crystal display (LCD) (e.g., a Liquid Crystal on Silicon (LCoS) LCD).

As another example, referring to FIG. 12, in some embodiments, an optical retarder 710 can be included in an optical pickup 701 used for reading and/or writing to an optical storage medium 720 (e.g., a CD or DVD). In addition to optical retarder 710, optical pickup 701 also includes a light source 730 (e.g., one or more laser diodes), a polarizing beam splitter 740, and a detector 750. Optical retarder has quarter wave retardation at wavelengths λ₁ and λ₂ (e.g., 660 nm and 785 nm, respectively). During operation, light source 730 illuminates a surface of medium 720 with linearly polarized radiation at λ₁ and/or λ₂ as the medium spins (indicated by arrow 721). The polarized radiation passes through polarizing beam splitter 740. Optical retarder 710 retards the polarized radiation, changing it from linearly polarized radiation to substantially circularly polarized radiation. The circularly polarized radiation changes handedness upon reflection from medium 720, and is converted back to linearly polarized radiation upon its second pass through optical retarder 710. At beam splitter 740, the reflected radiation is polarized orthogonally relative to the original polarization state of the radiation emitted from light source 730. Accordingly, polarizing beam splitter reflects the radiation returning from medium 720, directed it to detector 750. The retarder can be integrated with the PBS in this device. The PBS can be a metal wire-grid polarizer.

A number of embodiments of the invention have been described. Nevertheless, it will be understood that various modifications may be made without departing from the spirit and scope of the invention. Accordingly, other embodiments are within the scope of the following claims.

What is claimed is:

1. An article, comprising:
a first layer comprising a first material and having a surface with a cross-sectional profile comprising a plurality of portions and at least one peak and at least one trough; and
a second layer adjacent the first layer, the second layer comprising a second material and having a surface with a cross-sectional profile comprising a plurality of portions corresponding to the portions of the cross-sectional profile of the surface of the first layer and at least one peak and at least one trough,
wherein the corresponding portions have an angular orientation within about 10% or less of each other and a length within about 10% or less of each other, the first and second materials are different and the article is birefringent for a wavelength, λ, where λ is in a range from about 150 nm to about 2,000 nm.

2. The article of claim 1, further comprising a third layer adjacent the second layer, the third layer comprising a third material, wherein the second and third materials are different and the third layer has surface having a cross-sectional profile comprising a plurality of portions corresponding to the portions of the cross-sectional profile of the surface of the first layer.

3. The article of claim 2, wherein the first and third materials are the same.

4. The article of claim 2, further comprising a fourth layer adjacent the third layer, the fourth layer comprising a fourth material, wherein the third and fourth materials are different and the fourth layer has surface having a cross-sectional profile comprising a plurality of portions corresponding to the portions of the cross-sectional profile of the surface of the first layer.

5. The article of claim 4, wherein the second and fourth materials are the same.

6. The article of claim 1, wherein a perpendicular thickness of the second layer is substantially constant.

7. The article of claim 1, wherein the first layer extends in a plane and the portions of the cross-sectional profile of the surface of the first layer comprises a plurality of facets that are non-normal and non-parallel to the plane.

8. The article of claim 1, wherein the surface of the first layer has a periodic cross-sectional profile.

9. The article of claim 8, wherein the cross-sectional profile of the surface of the first layer has a period of about 2,000 nm or less.

10. The article of claim 8, wherein the cross-sectional profile of the surface of the first layer has a period of about 1,000 nm or less.

11. The article of claim 8, wherein the cross-sectional profile of the surface of the first layer has a period of about 500 nm or less.

12. The article of claim 8, wherein the cross-sectional profile of the surface of the first layer has a period of about 200 nm or less.

13. The article of claim 8, wherein a period of the cross-sectional profile of the surface of the first layer is triangular.

14. The article of claim 8, wherein a period of the cross-sectional profile of the surface of the first layer is trapezoidal.

15. The article claim 1, wherein the surface of the first layer has a saw-tooth cross-sectional profile.

16. The article of claim 1, wherein the article has a phase birefringence of about π/4 or more at λ.

17. The article of claim 1, wherein the article has a phase birefringence of about π/2 or more at λ.

18. The article of claim 1, wherein the article has a phase birefringence of about π or more at λ.

19. The article of claim 1, wherein the article has a phase birefringence of about 2π or more at λ.

20. The article of claim 1, wherein the article has a phase birefringence of about 4π or more at λ.

21. The article of claim 1, wherein the first material is a semiconductor material.

22. The article of claim 1, wherein the first material is a dielectric material.

23. The article of claim 1, wherein the first material comprises a material selected from the group consisting of SiNₓ:H_{z}, SiOₓN_{y}:H_{z}, Al₂O₃, Ta₂O₅, Nb₂O₅, TaNbₓO_{y}, TiNbₓO_{y}, HfO₂, TiO₂, SiO₂, ZnO, LiNbO₃, a-Si, Si, ZnSe, and ZnS.

24. The article of claim 1 wherein the second material is a semiconductor material.

25. The article of claim 1, wherein the second material is a dielectric material.

26. The article of claim 1, wherein the second material comprises a material selected from the group consisting of SiNₓ:H_{z}, SiOₓN_{y}:H_{z}, Al₂O₃, Ta₂O₅, Nb₂O₅, TaNbₓO_{y}, TiNbₓO_{y}, HfO₂, TiO₂, SiO₂, ZnO, LiNbO₃, a-Si, Si, ZnSe, and ZnS.

27. An article, comprising
a first layer comprising a first material and having a surface with a periodic cross-sectional profile comprising a plurality of portions; and
a second layer adjacent the first layer, the second layer comprising a second material and having a surface with a cross-sectional profile comprising a plurality of portions corresponding to the portions of the cross-sectional profile of the surface of the first layer,
wherein corresponding portions have an angular orientation within about 10% or less of each other and a length within about 10% or less of each other, the first and second materials are different and a period of the cross-sectional profile of the surface of the first layer is about 2,000 nm or less.

28. An article, comprising:
a first layer comprising a first material extending in a plane and comprising a surface having a plurality of facets that are non-normal and non-parallel to the plane, the surface of the first layer having a cross-sectional profile comprising at least one peak and at least one trough; and
a second layer adjacent the first layer, the second layer comprising a second material adjacent and having a perpendicular thickness that is substantially constant,
wherein the first and second materials are different and the article is birefringent for a wavelength, λ, where λ is in a range from about 150 nm to about 2,000 nm.

29. An article, comprising:
a first layer comprising a first material extending in a plane and comprising a surface having a plurality of facets that are non-normal and non-parallel to the plane and having a periodic cross-sectional profile; and
a second layer adjacent the first layer, the second layer comprising a second material and having a perpendicular thickness that is substantially constant,
wherein a period of the cross-sectional profile of the surface of the first layer is about 2,000 nm or less.

30. An article, comprising:
a plurality of layers each having a surface with saw-tooth cross-sectional profile,
wherein the article is birefringent for radiation having a wavelength, λ, from about 150 nm to about 2,000 nm.

31. A method, comprising:
forming a layer of a second material by sequentially depositing a plurality of monolayers of the second material, one of the monolayers of the second material being deposited on a surface of a layer of a first material having a cross-sectional profile comprising a plurality of portions and at least one peak and at least one trough,
wherein the layer of the second material comprises a surface with a cross-sectional profile comprising a plurality of portions corresponding to the portions of the cross-sectional profile of the surface of the layer of the first material and at least one peak and at least one trough, the corresponding portions have an angular orientation within about 10% or less of each other and a length within about 10% or less of each other, the first and second materials are different, and the article is birefringent for a wavelength, λ, where λ is in a range from about 150 nm to about 2,000 nm.

32. The method of claim 31, further comprising forming a layer of a third material by sequentially depositing a plurality of monolayers of the third material, one of the monolayers of the third material being deposited on the surface of the second layer.

33. The method of claim 32, wherein the layer of the third material comprises a surface having cross-sectional profile comprising a plurality of portions corresponding to the portions of the cross-sectional profile of the surface of the layer of the first material.

34. The method of claim 32, further comprising forming a layer of a fourth material by sequentially depositing a plurality of monolayers of the fourth material, one of the monolayers of the fourth material being deposited on a surface of the layer of the third material.

35. The method of claim 34, wherein the layer of the fourth material comprises a surface having cross-sectional profile comprising a plurality of portions corresponding to the portions of the cross-sectional profile of the surface of the layer of the first material.

36. The method of claim 31, wherein the monolayers are formed using atomic layer deposition.

37. The method of claim 31, further comprising forming the layer of the first material by etching an intermediate layer of the first material.

38. The method of claim 31, wherein the surface of the layer of the first material has a periodic cross-sectional profile.

39. The method of claim 31, wherein the surface of the layer of the first material has a saw-tooth cross-sectional profile.

40. A method, comprising:
forming a layer of a second material by sequentially depositing a plurality of monolayers of the second material, one of the monolayers of the second material being deposited on a surface of a layer of a first material having a periodic cross-sectional profile comprising a plurality of portions and having a period of about 2,000 nm or less,
wherein the first and second materials are different and the second layer has a surface comprising a plurality of portions each corresponding to a portion of the cross-sectional profile of the surface of the layer of the first material.
